(19) United States
(12) Patent Application Publication
(10) Pub. No.: US 2009/0289367 A1
(43) Pub. Date: Nov. 26, 2009

(54) SEMICONDUCTOR DEVICE AND METHOD OF MANUFACTURING THE SAME

(75) Inventors: Daisuke KODAMA, Tokyo (JP); Shoichi Fukui, Tokyo (JP); Hiroshi Miyazaki, Tokyo (JP); Tatsunori Murata, Tokyo (JP)

Correspondence Address: MCDERMOTT WILL & EMERY LLP, 600 13TH STREET, N.W., WASHINGTON, DC, 20005-3096, US

(73) Assignee: RENESAS TECHNOLOGY CORP.

(21) Appl. No.: 12/472,100

(22) Filed: May 26, 2009

(30) Foreign Application Priority Data
May 26, 2008 (JP) 2008-137023(P)
Mar. 3, 2009 (JP) 2009-049552(P)

(51) Int. Cl. H01L 23/522; H01L 21/768

(52) U.S. Cl. 257/751; 438/643; 257/E23.142; 257/E21.584

(57) ABSTRACT

A copper interconnection layer is formed in an interconnection trench at a surface of an interlayer insulating film. A diffusion preventing insulating film is formed to cover the copper interconnection layer and is made of at least one of SiC and SiCN. An insulating film is formed on the copper interconnection layer with the diffusion preventing insulating film interposed and is made of SiN.

### BACKGROUND OF THE INVENTION

1. Field of the Invention

The present invention relates to a semiconductor device and a method of manufacturing the same, and more particularly to a semiconductor device having interconnections including copper (Cu) and a method of manufacturing the same.

2. Description of the Background Art

With higher performance and higher functionality of semiconductor devices, the problem of wiring delay becomes conspicuous. In the wiring using copper, there are three reliability problems, namely, electromigration (EM), stress migration (SM) or stress-induced voiding (SIV), and time-dependent dielectric breakdown (TDDB). Among them, electromigration resistance affects a permissible current value in circuit designing and is therefore a major issue that should be improved together with higher performance at each miniaturization.

Known as important techniques for next-generation devices are, for example, a cap metal technique of covering the top surface of damascene copper interconnection, a technique of adding another element to copper for alloying, and the like. These methods are effective both in electromigration in interconnection and electromigration in via.

The above-noted cap metal technique is disclosed, for example, in C.-K. Hu et al., “Reduced electromigration of Cu wires by surface coating,” APPLIED PHYSICS LETTERS, 2 SEPTEMBER 2002, VOL. 81, No. 10, pp. 1782-1784.

Furthermore, the above-noted alloying technique is disclosed, for example, in K. L. Lee et al., “In situ scanning electron microscope comparison studies on electromigration of Cu and Cu (Sn) alloys for advanced chip interconnects.” J. Appl. Phys. 78(7), 1 Oct. 1995, pp. 4428-4437.

Unfortunately, the resistance is increased because of the increased proportion of high resistance portions in wiring volume in the former cap metal technique and because of electron scattering of the added element in the latter alloying technique. As discussed above, higher performance and higher density makes it hard to ensure the electromigration reliability, and therefore development of improved techniques is imperative.

### SUMMARY OF THE INVENTION

The present invention is made in view of the aforementioned problem, and it is an object of the present invention to provide a semiconductor device and a method of manufacturing the same, which allows electromigration reliability to be improved with a wiring resistance kept low.

A semiconductor device in the present embodiment includes an interlayer insulating film, an interconnection layer including copper, a diffusion preventing insulating film, and an insulating film. The interconnection layer including copper is formed in the interlayer insulating film. The diffusion preventing insulating film is formed to cover the interconnection layer including copper and is made of at least one of silicon carbide (SiC) and silicon carbide nitride (SiCN). The insulating film is formed on the interconnection layer including copper with the diffusion preventing insulating film interposed and is made of silicon nitride (SiN).

In accordance with the semiconductor device of the present embodiment, since SiN as an insulating film has a high elasticity modulus (Young's modulus) intrinsic to the material, it serves to suppress the volumetric expansion of the interconnection layer when the interconnection layer is heated. Thus, the force of the interconnection layer expanding is present in the interior of the interconnection layer and compressive stress develops in the interior of the interconnection layer. Here, if the internal stress of the interconnection layer reaches the critical stress of the tension side, voids are easily formed in the interconnection layer. In the present embodiment, however, because of the compressive stress in the interior of the interconnection layer, the internal stress of the interconnection layer hardly reaches the critical stress of the tension side. Accordingly, voids formation in the interior of the interconnection layer can be prevented, thereby improving electromigration reliability.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross-sectional view schematically showing a structure of a semiconductor device in a first embodiment of the present invention.

FIG. 2 to FIG. 13 are cross-sectional views schematically showing the steps of a method of manufacturing the semiconductor device, in order, in the first embodiment of the present invention.

FIG. 14 is a cross-sectional view schematically showing a structure of a test sample for examining the relation between internal stress of an insulating film SI and electromigration lifetime.

FIG. 15 is a graph showing the relation between distortion of insulating film SI and electromigration lifetime.

FIG. 16 is a cross-sectional view schematically showing a structure of a semiconductor device in accordance with a third embodiment of the present invention.

FIG. 17 to FIG. 25 are cross-sectional views schematically showing the steps of a method of manufacturing the semiconductor device, in order, in the third embodiment of the present invention.

FIG. 26 is a cross-sectional view schematically showing a structure of a comparative example in which an insulating layer formed of SiN is eliminated from the structure shown in FIG. 16.

FIG. 27 is a graph showing the relation between the thickness of an interlayer insulating film on a copper interconnection layer and electromigration lifetime.

FIG. 28 is a cross-sectional view schematically showing a structure of a semiconductor device in a fourth embodiment of the present invention.

FIG. 29 to FIG. 35 are cross-sectional views schematically showing a method of manufacturing the semiconductor device, in order, in the fourth embodiment of the present invention.

FIG. 36 is a cross-sectional view schematically showing a structure of a comparative example in which an insulating layer formed of SiN is eliminated from the structure shown in FIG. 28.

FIG. 37 is a schematic plan view illustrating a pad conductive layer including a pad portion and an interconnection portion.

### DESCRIPTION OF THE PREFERRED EMBODIMENTS

In the following, the embodiments of the present invention will be described based on the drawings.

### First Embodiment

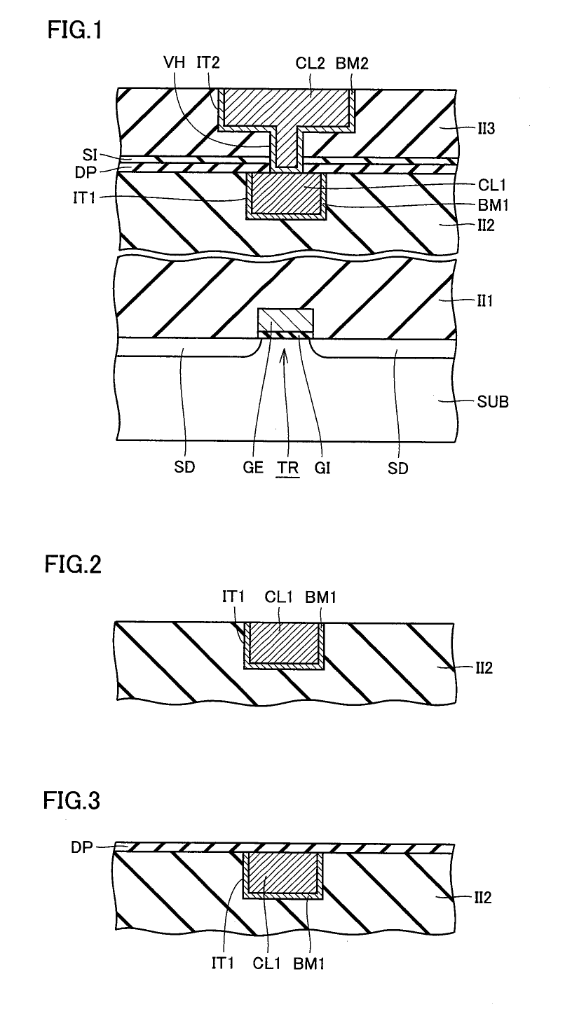

Referring to FIG. 1, a semiconductor device in accordance with the present embodiment has a multilevel interconnect structure in which a number of copper interconnection layers are stacked. This multilevel copper interconnect is formed to electrically connect elements including MOS (Metal Oxide Semiconductor) transistors TR with each other, which are formed at the main surface of a semiconductor substrate SUB.

MOS transistor TR has a pair of source/drain regions SD, a gate insulating film GI, and a gate electrode layer GE. The pair of source/drain regions SD is formed spaced apart from each other at the main surface of semiconductor substrate SUB. Gate electrode layer GE is formed with gate insulating film GI interposed on a region of semiconductor substrate SUB sandwiched between the pair of source/drain regions SD. An interlayer insulating film II1 is formed at the main surface of semiconductor substrate SUB to cover this MOS transistor TR. A copper interconnection layer constituting a multilevel copper interconnect is formed on interlayer insulating film II1.

Although only two copper interconnection layers are shown for the sake of simplicity, three or more layers may be provided. The copper interconnect structure will be described below.

An interlayer insulating film II2 is formed directly or with another interlayer insulating film interposed on interlayer insulating film II1. Interlayer insulating film II2 may be the same insulating film as interlayer insulating film II1. An interconnection trench IT1 is formed at the surface of interlayer insulating film II2. A via hole reaching the underlying interconnection layer from the bottom of interconnection trench IT1 may be formed in interlayer insulating film II2.

A barrier metal layer BM1 is formed along the wall surface of interconnection trench IT1. A copper interconnection layer CL1 is formed to fill in interconnection trench IT1. Copper interconnection layer CL1 is formed of a material including copper, for example, copper (Cu), copper-aluminum (CuAl), or the like. It is noted that in the following a layer formed of a similar material is referred to as “copper interconnection layer.”

A diffusion preventing insulating film DP is formed to cover copper interconnection layer CL1. Diffusion preventing insulating film DP is formed of at least one of SiC and SiCN. An insulating film SI is formed on copper interconnection layer CL1 with diffusion preventing insulating layer DP interposed. Insulating film SI is formed of SiN.

Insulating film SI has the modulus of elasticity higher than that of diffusion preventing insulating film DP. Since insulating film SI is formed of SiN, the modulus of elasticity thereof is 150 GPa or more and 250 GPa or less. When diffusion preventing insulating film DP is formed of SiC, the modulus of elasticity of diffusion preventing insulating film DP is approximately 60 GPa-65 GPa. When diffusion preventing insulating film DP is formed of SiCN, the modulus of elasticity of diffusion preventing insulating film DP is approximately 130 GPa-135 GPa.

An interlayer insulating film II3 is formed on insulating film SI. An interconnection trench IT2 is formed at the surface of interlayer insulating film II3. A via hole VH passing through insulating film SI and diffusion preventing insulating film DP from the bottom of interconnection trench IT2 to reach the underlying copper interconnection layer CL1 is also formed in interlayer insulating film II3.

A barrier metal layer BM2 is formed along the wall surfaces of interconnection trench IT2 and via hole VH. A copper interconnection layer CL2 is formed to fill in interconnection trench IT2 and via hole VH. Copper interconnection layer CL2 is formed of a material including copper, for example, copper, copper-aluminum, or the like. That part of copper interconnection layer CL2 which is formed in interconnection trench IT2 is an interconnection portion and that part which is formed in via hole VH is a contact portion.

A method of manufacturing the semiconductor device in accordance with the present embodiment will be described.

It is noted that in the present embodiment a method of forming the interconnect by a general “via first process (a process of performing patterning of a connection hole first” will be described. For the sake of simplicity, the description will be made only to a method of manufacturing the multilevel copper interconnect part.

Referring to FIG. 2, interlayer insulating film II2 formed of a low dielectric constant insulating film is formed on a semiconductor substrate made of, for example, silicon. Interconnection trench IT1 is formed at the surface of interlayer insulating film II2 by the usual photolithography and etching techniques.

Barrier metal layer BM1 is formed along the surface of interlayer insulating film II2 and the wall surface of interconnection trench IT1. A conductive layer CL1 made of a material including copper is formed on interlayer insulating film II2 to fill in interconnection trench IT1. Thereafter, polishing is performed on conductive layer CL1 and the like, for example, by CMP (Chemical Mechanical Polishing). Thus, the surface of interlayer insulating film II2 is exposed and barrier metal layer BM1 and conductive layer CL1 are left in interconnection trench IT1. Copper interconnection layer CL1 formed of conductive layer CL1 is thus formed, for example, at a thickness of 250 nm to fill in interconnection trench IT1.

Referring to FIG. 3, diffusion preventing insulating film DP is formed, for example, by CVD as a cap insulating film on interlayer insulating film II2 and copper interconnection layer CL1. Diffusion preventing insulating film DP serves as an etching stopper and serves to prevent copper diffusion at a time of via hole formation described later. As the process conditions of formation of diffusion preventing insulating film DP, for example, the chamber pressure is 100 Pa-1000 Pa, RF (Radio Frequency) is 200 W-800 W, the gas flow rate is 100 sccm-500 sccm, and the deposition temperature is 300° C.-450° C.

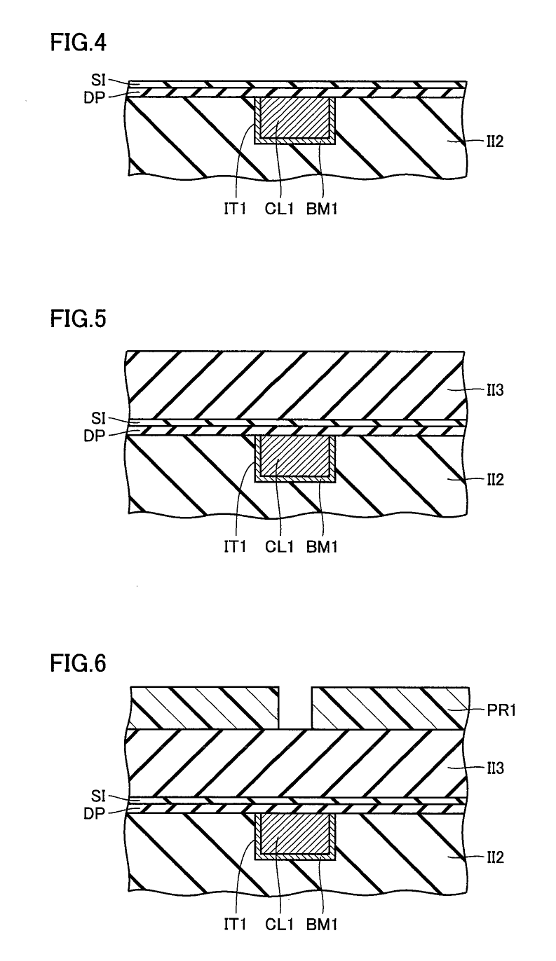

Referring to FIG. 4, insulating film SI made of SiN is formed on diffusion preventing insulating film DP, for example, by CVD. As the process conditions, for example, the chamber pressure is 100 Pa-1000 Pa, RF is 10 W-200 W, the electrode-to-electrode distance is 5 mm-15 mm, the gas flow rate is silane (SiH₄): 10 sccm-500 sccm, NH₃: 10 sccm-500 sccm, N₂: 10 sccm-50000 sccm, and the deposition temperature is 200° C.-450° C.

Insulating film SI is preferably deposited so that the modulus of elasticity is 150 GPa-250 GPa and the internal stress after deposition is −3.5 GPa or more and −1 GPa or less (in other words, compressive stress of 1 GPa or more and 3.5 GPa or less).

Referring to FIG. 5, interlayer insulating film II3 is formed on insulating film SI.

Referring to FIG. 6, a photoresist PR1 is applied on interlayer insulating film II3. Photoresist PR1 is patterned by the usual photolithography technique. Using the patterned resist pattern PR1 as a mask, anisotropic etching is performed on interlayer insulating film II3 and insulating film SI. Thereafter, photoresist PR1 is removed, for example, by ashing.

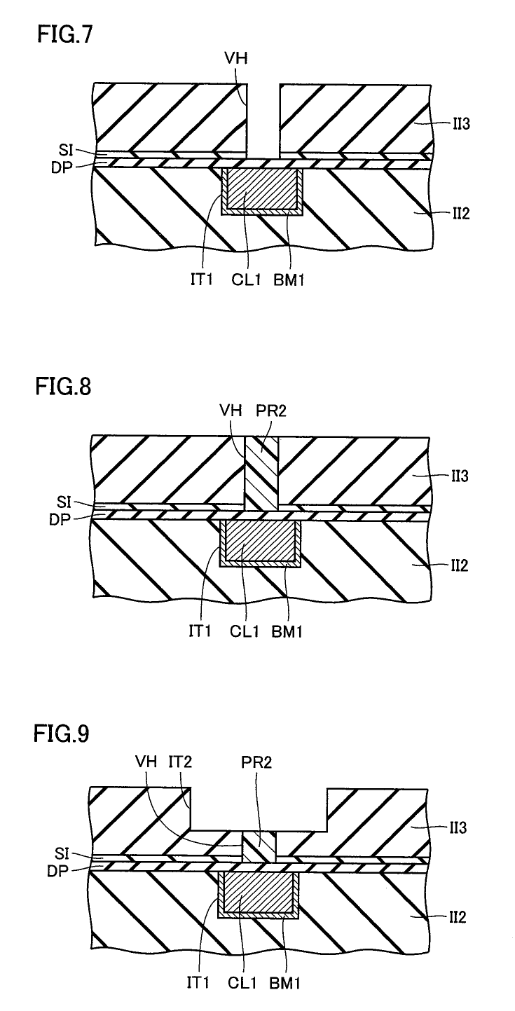

Referring to FIG. 7, in the aforementioned etching, diffusion preventing insulating film DP functions as an etching stopper. A hole VH is thus formed which passes through interlayer insulating film II3 and insulating film SI to reach diffusion preventing insulating film DP.

Referring to FIG. 8, a resist plug PR2 is buried in hole VH.

Referring to FIG. 9, interconnection trench IT2 is formed at the surface of interlayer insulating film II3 by the usual photolithography and etching techniques. Resist plug PR2 serves to protect the bottom portion of hole VH from the etching for forming the interconnection trench.

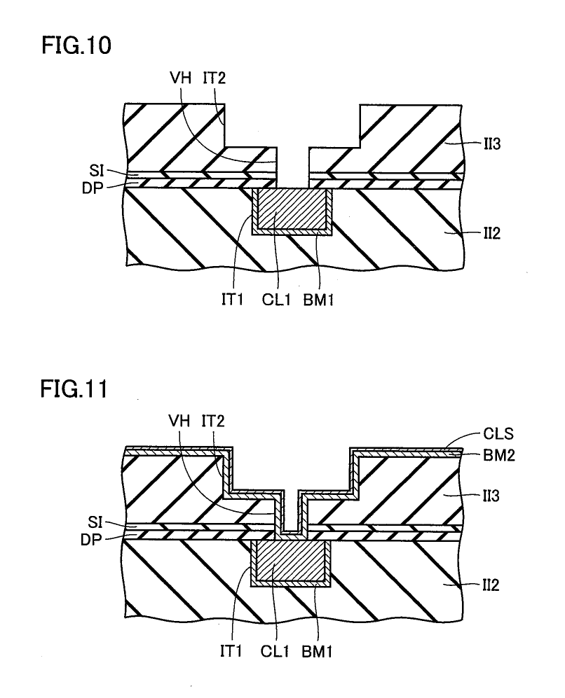

Referring to FIG. 10, resist plug PR2 in hole VH is removed and diffusion preventing insulating film DP exposed at the bottom portion of hole VH is removed, so that a surface of copper interconnection layer CL1 is partially exposed. Via hole VH is thus formed which reaches copper interconnection layer CL1 from the bottom portion of interconnection trench IT2.

Referring to FIG. 11, barrier metal layer BM2 is formed along the surface of interlayer insulating film II3, the wall surface of interconnection trench IT2 and the wall surface of via hole VH, for example, by sputtering. A copper seed layer CLS is formed on barrier metal layer BM2, for example, by sputtering. A copper film is thereafter formed on seed layer CLS, for example, by plating.

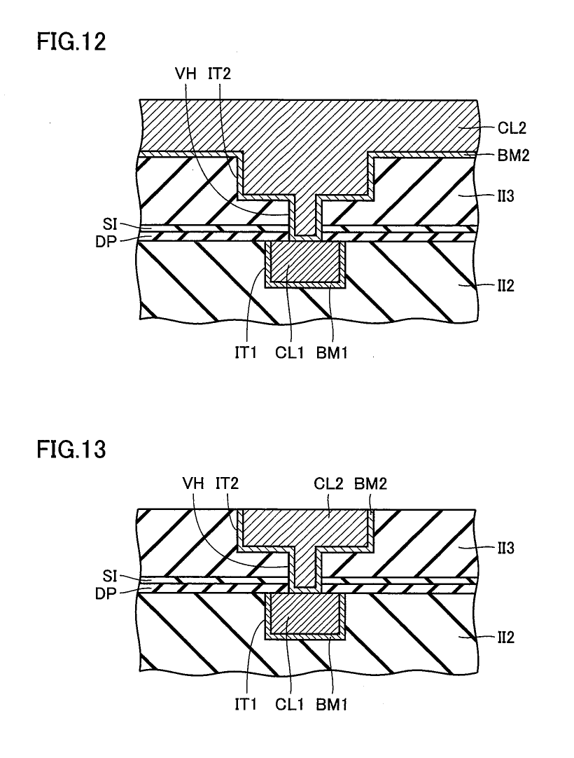

Referring to FIG. 12, conductive layer CL2 made of copper is formed on interlayer insulating film II3 to fill in interconnection trench IT2 and via hole VH by the above-noted plating. Polishing is thereafter performed on conductive layer CL2 and the like, for example, by CMP.

Referring to FIG. 13, the above-noted CMP exposes the surface of interlayer insulating film II3 and also leaves barrier metal layer BM2 and conductive layer CL2 in interconnection trench IT2 and via hole VH. Copper interconnection layer CL2 formed of conductive layer CL2 is thus formed, for example, at a thickness of 500 nm to fill in interconnection trench IT2 and via hole VH.

Through the aforementioned steps, a multilevel copper interconnect, for example, including two layers, is formed. A multilevel copper interconnect of three or more layers is formed by repeating the steps described above.

In accordance with the present embodiment, SiN as insulating film SI shown in FIG. 1 has a high elasticity modulus (Young's modulus) of 150 GPa or more and 250 GPa or less and therefore acts to suppress volumetric expansion of copper interconnection layer CL1 when copper interconnection layer CL1 is heated. Accordingly, the force of copper interconnection layer CL1 expanding exists in the interior of copper interconnection layer CL1 and compressive stress develops in the interior of copper interconnection layer CL1. When the internal stress of copper interconnection layer CL1 attains the critical stress of the tension side, voids are easily produced in copper interconnection layer CL1 because of electromigration. In the present embodiment, however, compressive stress develops in the interior of copper interconnection layer CL1 so that the internal stress of copper interconnection layer CL1 hardly attains the critical stress of the tension side. Accordingly, electromigration-induced voids can be prevented.

More specifically, in the evaluation of electromigration, when the temperature of the copper interconnection layer is increased to 300° C., the copper interconnection layer is brought into the almost stress-free state due to thermal expansion. When current stress is applied to the copper interconnection layer in this state, the holes in the copper interconnection layer are gathered to the negative electrode. Since the hole density and the stress in the copper interconnection layer are bound by the thermal equilibrium relation, the tensile stress increases with increasing hole density. Here, arrangement of an insulating film with a high elasticity modulus on the copper interconnection layer causes compressive stress in the copper interconnection layer. Therefore, the critical stress for void formation due to electromigration becomes higher to the tension side and the increasing speed of the tensile stress becomes faster. Here, the effect of the higher critical stress is superior to the effect of the improved increasing speed of the tensile stress, and as a result, the time for the stress in the copper interconnection layer to reach the critical stress becomes longer, thereby improving the electromigration resistance.

As described above, insulating film SI formed of SiN can prevent electromigration, so that it is no longer necessary to arrange a cap metal covering copper interconnection layer CL1 and in addition it is no longer necessary to add another element to copper forming copper interconnection layer CL1 for alloying. Accordingly, the resistance of copper interconnection layer CL1 can be kept low.

Furthermore, since insulating film SI formed of SiN has a high elasticity modulus as described above, in the case where insulating film SI is formed in direct contact with copper interconnection layer CL1, it is likely that the volumetric expansion of copper interconnection layer CL1 caused by heating is excessively suppressed to cause cracks in copper interconnection layer CL1.

In the present embodiment, diffusion preventing insulating film DP is formed between copper interconnection layer CL1 and insulating film SI. Since diffusion preventing insulating film DP has the modulus of elasticity lower than that of insulating film SI, the volumetric expansion of copper interconnection layer CL1 caused by heating is not excessively suppressed and cracks in copper interconnection layer CL1 can be prevented.

In addition, in accordance with the present embodiment, diffusion preventing insulating film DP is formed in direct contact with copper interconnection layer CL1, so that diffusion of copper from copper interconnection layer CL1 toward interlayer insulating film II3 can be suppressed better than the case where insulating film SI formed of SiN is formed on copper interconnection layer CL1 in direct contact therewith. Diffusion preventing insulating film DP is formed of at least one of SiC and SiCN. Each of SiC and SiCN has the dielectric constant lower than that of SiN, so that the interlayer capacitance can be decreased. Moreover, in each of SiC and SiCN, the effect of preventing copper diffusion is high and the amount of leak current in line-to-line TDDB evaluation is small.

### Second Embodiment

In the present embodiment, referring to FIG. 1, insulating film SI has the internal stress of −1 GPa or less (i.e. compressive stress of 1 GPa or more). Insulating film SI preferably has the internal stress of −3.5 GPa or more (i.e. compressive stress of 3.5 GPa or less).

Except for that mentioned above, the structure of the present embodiment is similar to the structure in the first embodiment. Therefore, the same elements are denoted with the same reference characters and the description will not be repeated.

The present inventors examined the internal stress of insulating film SI and the electromigration life as follows.

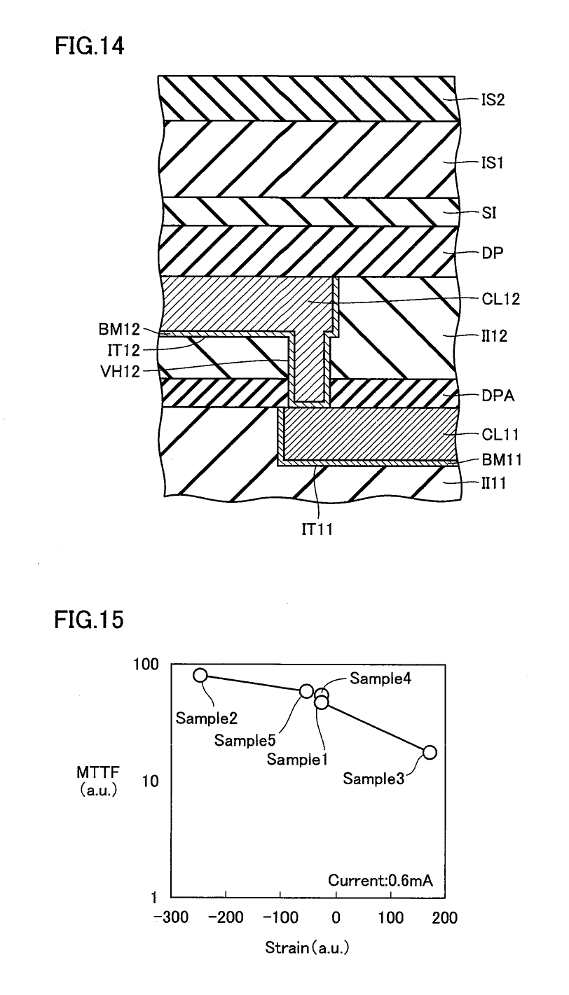

First, a test sample having the structure shown in FIG. 14 was prepared. This test sample has two copper interconnection layers CL11, CL12. Diffusion preventing insulating film DP of SiCN and insulating film SI of SiN are stacked on the upper copper interconnection layer CL12.

The lower copper interconnection layer CL11 is formed in an interconnection trench IT11 provided in an interlayer insulating film II11 with a barrier metal layer BM11 interposed. A diffusion preventing insulating film DPA and an interlayer insulating film II12 are formed in a stacked manner on copper interconnection layer CL11 and interlayer insulating film II11.

The upper copper interconnection layer CL12 is formed in a via hole VH12 and an interconnection trench IT12 provided in interlayer insulating film II12 with a barrier metal layer BM12 interposed. Diffusion preventing insulating film DP and insulating film SI described above are formed in a stacked manner on copper interconnection layer CL12 and interlayer insulating film II12.

A silicon oxide film IS1 and a silicon nitride film IS2 are formed in a stacked manner on insulating film SI.

In the above-noted test structure, the electromigration life was examined with the combinations of the thickness of diffusion preventing insulating film DP and the internal stress of insulating film SI as shown in Table 1 below and with current stress applied to allow electrons to move from copper interconnection layer CL12 to copper interconnection layer CL11 in FIG. 14. The result is shown in FIG. 15.

In Table 1, “W/O” means that diffusion preventing insulating film DP or insulating film SI is not formed.

TABLE 1

| sample No. | | | | |
|---|---|---|---|---|
| 1 | 2 | 3 | 4 | 5 |

| | | | |
|---|---|---|---|
| diffusion | SiCN = | SiCN = 10 nm | W/O |
| preventing | 175 nm | | |
| insulating | | | |
| film DP | | | |

| | | |
|---|---|---|
| insulating | W/O | SiN = 175 nm |

| | | | | |
|---|---|---|---|---|
| film SI | −1.4 GPa | +1.0 GPa | −0.15 GPa | −0.3 GPa |

In FIG. 15, the axis of abscissas represents strain and the axis of ordinates represents MTTF (Mean Time to Failure). The strain represented by the axis of abscissas is the product of the thickness of insulating film SI and the internal stress of insulating film SI. MTTF represented by the axis of ordinates is the mean operating time until a failure occurs. The units of strain and MTTF are arbitrary units.

The result in FIG. 15 shows that MTTF is high when the internal stress of insulating film SI is set to −1.4 GPa less than −1 GPa. This is presumably because the internal stress of −1 GPa or less in insulating film SI causes the internal stress of the underlying copper interconnection layer CL12 to shift from the tension side to the compression side, so that the critical stress for void formation on the tension side is hardly reached.

However, when the distance between insulating film SI and copper interconnection layer CL12 is increased, the stress effect of insulating film SI on copper interconnection layer CL12 is reduced. Therefore, the distance between insulating film SI and copper interconnection layer CL12 is preferably as short as possible, preferably, for example, 30 nm or shorter.

As described above, in accordance with the present embodiment, the internal stress of insulating film SI is −1 GPa or less (i.e. compressive stress of 1 GPa or more), so that the electromigration life can be further improved.

In the foregoing first and second embodiments, in the case of the multilevel copper interconnect, a stacked structure of diffusion preventing insulating film DP and insulating film SI may be formed on any given copper interconnection layer. In other words, the stacked structure of diffusion preventing insulating film DP and insulating film SI may be applied on only one copper interconnection layer of the multilevel copper interconnect, or the stacked structure of diffusion preventing insulating film DP and insulating film SI may be applied on all the copper interconnection layers, or the stacked structure of diffusion preventing insulating film DP and insulating film SI may be applied on some copper interconnection layers.

Furthermore, the stacked structure of diffusion preventing insulating film DP and insulating film SI may be applied to either an SG (semi-global) layer or a global layer. In either case, the electromigration improvement effect can be expected.

### Third Embodiment

A structure in which the aforementioned stacked structure of the diffusion preventing insulating film and the insulating film of SiN is applied to the uppermost copper interconnection layer (i.e. global layer) connected to a conductive layer for a wire bonding pad will be described below as the third and fourth embodiments.

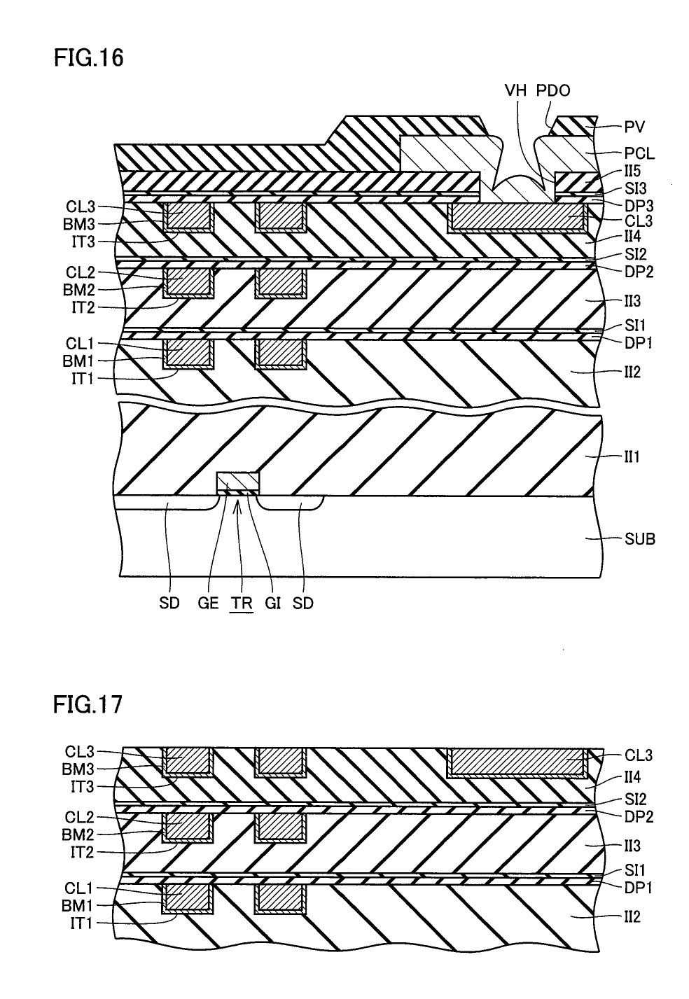

Referring to FIG. 16, a semiconductor device in the present embodiment mainly has an element of a MOS transistor TR or the like formed on a semiconductor substrate, multilevel copper interconnect CL1-CL3 formed on the element, and a pad conductive layer PCL formed thereon.

The uppermost copper interconnection layer CL3 of multilevel copper interconnect CL1-CL3 is formed to fill in an interconnection trench IT3 formed in an interlayer insulating film II4. A barrier metal layer BM3 is formed along the wall surface of interconnection trench IT3 between copper interconnection layer CL3 and interlayer insulating film II4.

A stacked structure of a diffusion preventing insulating film DP3 and an insulating film SI3 of SiN is formed to cover the uppermost copper interconnection layer CL3. Diffusion preventing insulating film DP3 is formed of at least one of SiC and SiCN. An insulating film SI3 is formed on copper interconnection layer CL3 with diffusion preventing insulating film DP3 interposed. Insulating film SI3 is formed of SiN.

Insulating film SI3 has the modulus of elasticity higher than that of diffusion preventing insulating film DP3. Insulating film SI3 formed of SiN has the modulus of elasticity of 150 GPa or more and 250 GPa or less. When diffusion preventing insulating film DP3 is formed of SiC, the modulus of elasticity of diffusion preventing insulating film DP3 is approximately 60 GPa-65 GPa. When diffusion preventing insulating film DP3 is formed of SiCN, the modulus of elasticity of diffusion preventing insulating film DP3 is approximately 130 GPa-135 GPa.

An interlayer insulating film II5 is formed on insulating film SI3. In interlayer insulating film II5, insulating film SI3, and diffusion preventing insulating film DP3, via hole VH is formed which passes through these films II5, S13, DP3 to reach copper interconnection layer CL3.

Pad conductive layer PCL is formed on interlayer insulating film II5 to electrically connect with copper interconnection layer CL3 through via hole VH. Pad conductive layer PCL is formed of, for example, aluminum (Al). Pad conductive layer PCL is formed in via hole VH and thus directly connected with copper interconnection layer CL3.

A passivation film PV is formed on pad conductive layer PCL. Passivation film PV has an opening PDO. The surface of a pad portion of pad conductive layer PCL is exposed from opening PDO.

Except for those mentioned above, the structure of the present embodiment is almost the same with the structure of the first embodiment shown in FIG. 1. Therefore the same elements are denoted with the same reference characters and the description will not be repeated. In the structure of the present embodiment shown in FIG. 16, diffusion preventing insulating film DP2 and insulating film SI2 formed to cover copper interconnection layer CL2 have almost the same structures with those of the above-noted diffusion preventing insulating film DP3 and insulating film SI3, respectively, and therefore the description thereof will also not be repeated.

Now, a method of manufacturing the semiconductor device in accordance with the present embodiment will be described.

In the manufacturing method in the present embodiment, first, the steps shown in FIG. 2-FIG. 13 are repeated. Thus, as shown in FIG. 17, a number of (for example, three levels) copper interconnection layers CL1, CL2, CL3 are formed.

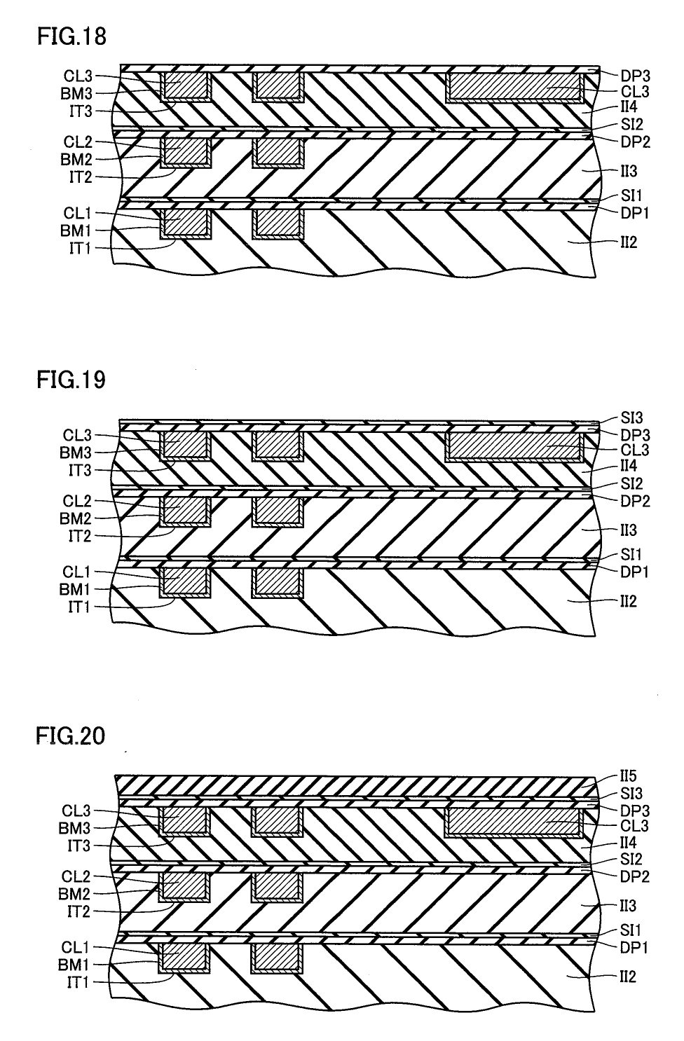

Referring to FIG. 18, after the uppermost copper interconnection layer CL3 is formed by polishing by CMP, diffusion preventing insulating film DP3 of SiC is formed as a cap insulating film on interlayer insulating film II4 and copper interconnection layer CL3, for example, by CVD. Diffusion preventing insulating film DP3 serves as an etching stopper and serves to prevent copper diffusion at a time of via hole formation as described later. As the process conditions of formation of diffusion preventing insulating film DP3, for example, the chamber pressure is 100 Pa-1000 Pa, RF is 200 W-800 W, the gas flow rate is 100 sccm-500 sccm, and the deposition temperature is 300° C.-450° C.

Referring to FIG. 19, insulating film SI3 of SiN is formed on diffusion preventing insulating film DP3, for example, by CVD. As the process conditions, for example, the chamber pressure is 100 Pa-1000 Pa, RF is 10 W-200 W, the electrode-to-electrode distance is 5 mm-15 mm, the gas flow rate is silane (SiH₄): 10 sccm-500 sccm, NH₃: 10 sccm-500 sccm, N₂: 10 sccm-50000 sccm, and the deposition temperature is 200° C.-450° C.

Preferably, insulating film SI3 is deposited so that the modulus of elasticity is 150 GPa-250 GPa and the internal stress after deposition is −3.5 GPa or more and −1 GPa or less (i.e. compressive stress of 1 GPa or more and 3.5 GPa or less).

Referring to FIG. 20, interlayer insulating film II5 is formed, for example, at a thickness of 300 nm or less on insulating film SI3.

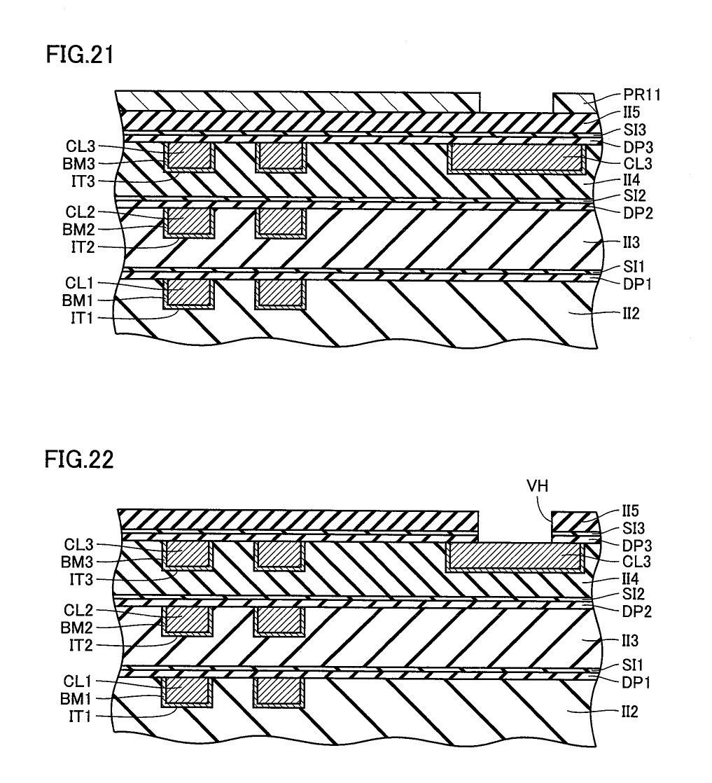

Referring to FIG. 21, a photoresist PR11 is applied on interlayer insulating film II5. Photoresist PR11 is patterned by the usual photolithography technique. Using the patterned resist pattern PR11 as a mask, anisotropic etching is performed on interlayer insulating film II5, insulating film SI3, and diffusion preventing insulating film DP3. Photoresist PR1 is removed, for example, by ashing.

Referring to FIG. 22, through the above-noted etching, via hole VH is formed which passes through interlayer insulating film II5, insulating film SI3, and diffusion preventing insulating film DP3 to reach copper interconnection layer CL3.

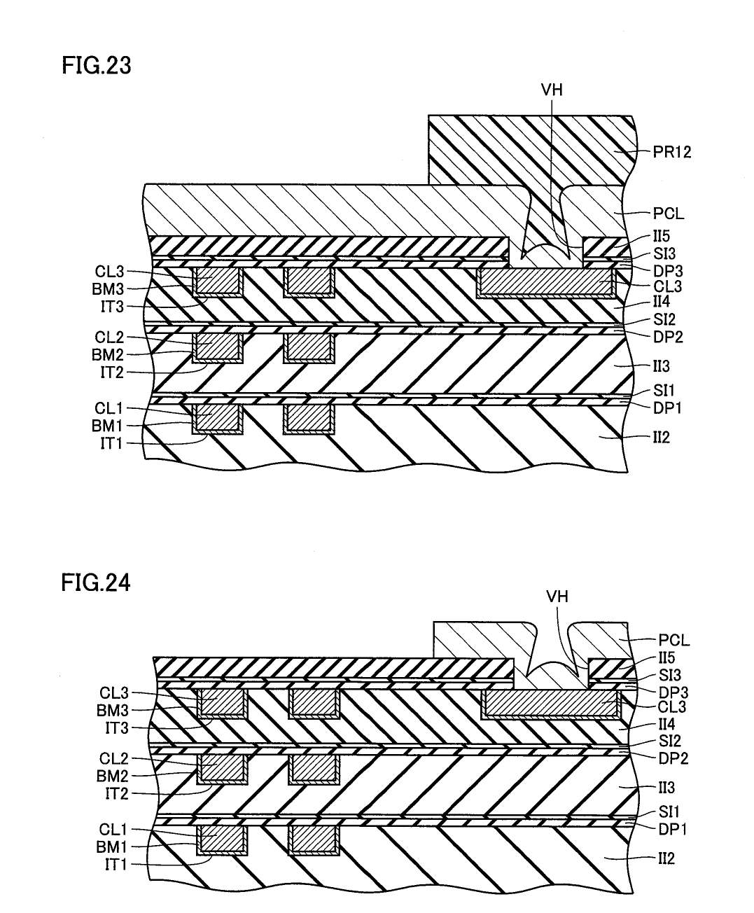

Referring to FIG. 23, conductive layer PCL, for example, of Al is formed by sputtering on interlayer insulating film II5 to be in direct contact with copper interconnection layer CL3 through via hole VH. A photoresist PR12 is applied on conductive layer PCL. Photoresist PR12 is patterned by the usual photolithography technique. Using the patterned photoresist pattern PR12 as a mask, anisotropic etching is performed on conductive layer PCL. Photoresist PR12 is thereafter removed, for example, by ashing.

Referring to FIG. 24, conductive layer PCL is patterned by the aforementioned etching thereby forming pad conductive layer PCL.

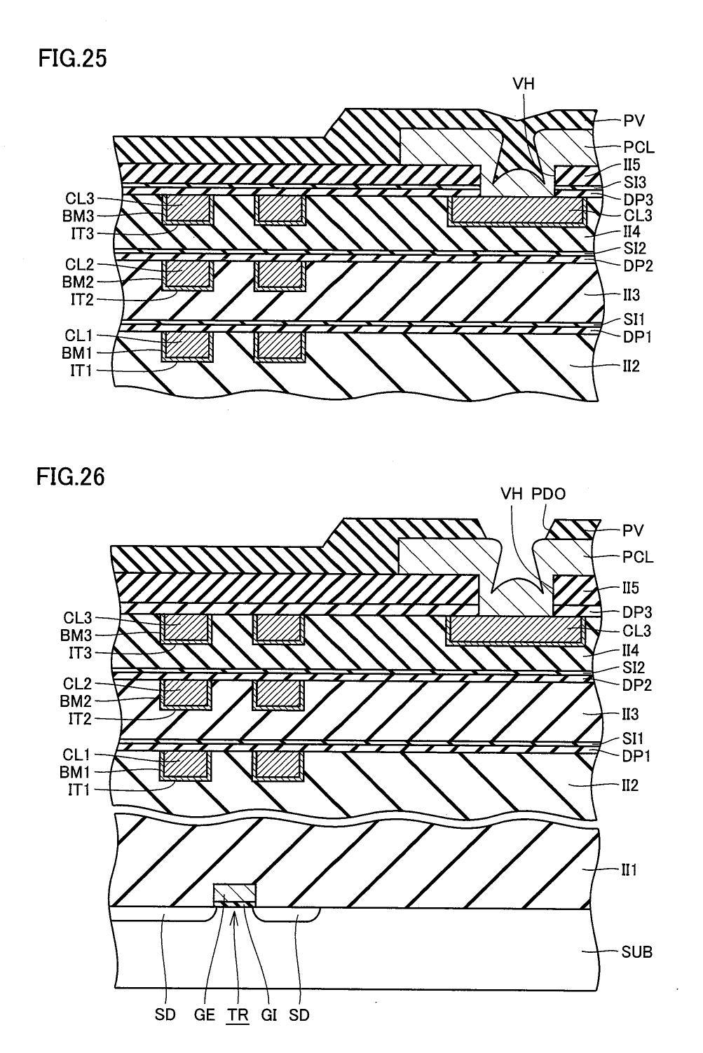

Referring to FIG. 25, a moisture protection film PV called passivation is formed, for example, by CVD to cover pad conductive layer PCL. Passivation film PV is patterned by the usual photolithography and etching techniques. As a result, as shown in FIG. 16, opening PDO is formed in passivation film PV so that the surface of the pad portion of pad conductive layer PCL is exposed from opening PDO.

Through the aforementioned steps, the semiconductor device in the present embodiment is manufactured.

The operative effect of the present embodiment will now be described in comparison with a comparative example.

Referring to FIG. 26, the comparative example is structured by eliminating insulating film SI3 of SiN from the structure of the present embodiment shown in FIG. 16. Except for this, the structure of the comparative example shown in FIG. 26 is almost the same with the structure shown in FIG. 16. Therefore, the same elements are denoted with the same reference characters and the description will not be repeated.

Referring to FIG. 26, with the recent miniaturization and increased density of devices, the number of devices (for example, MOS transistors TR) formed in one semiconductor chip increases. With the increased number of devices, the total amount of current applied to one semiconductor chip is increased, so that the current density in the uppermost copper interconnection layer CL3 becomes higher. Accordingly, it is likely that electromigration easily occurs in the uppermost copper interconnection layer CL3.

The present inventors has found that in order to prevent the aforementioned electromigration, it is effective to increase the thickness of interlayer insulating film II5 on copper interconnection layer CL3.

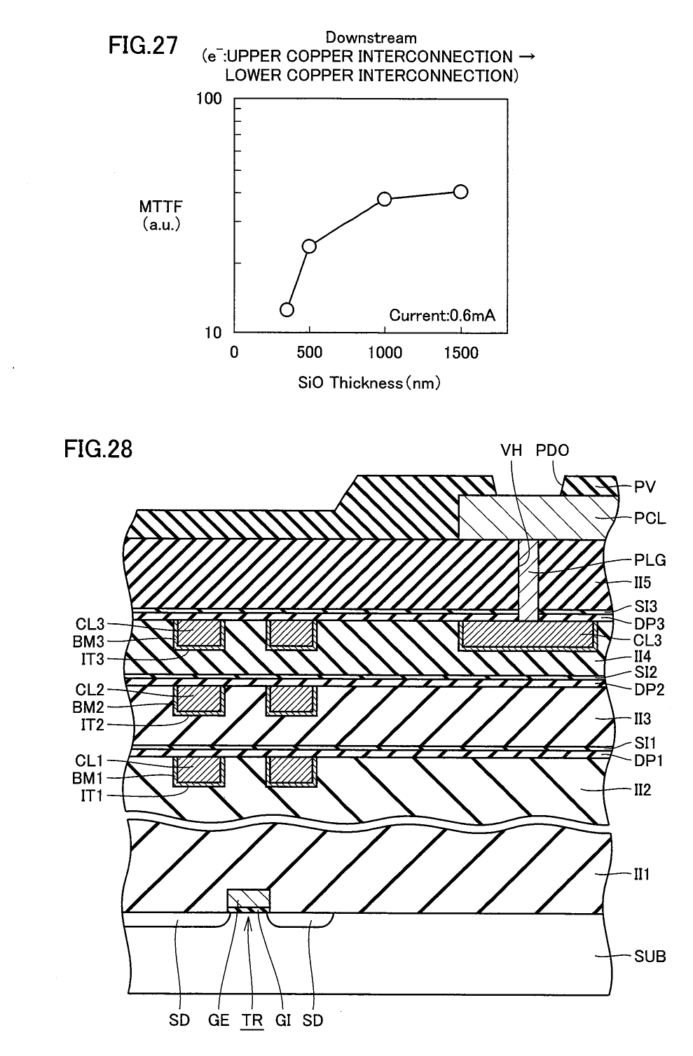

FIG. 27 is a graph showing the relation between the thickness of the interlayer insulating film (SiO Thickness) on the copper interconnection layer and the electromigration life (MTTF) as found by the present inventors. The result shown in FIG. 27 is obtained by studying how the electromigration life changes with changing thickness of interlayer insulating film IS1 when current stress (current value 0.6 mA) is applied to allow electrons to move from copper interconnection layer CL12 to copper interconnection layer CL11 in the structure formed by eliminating insulating film SI from the test structure shown in FIG. 14.

As is clear from the result in FIG. 27, it can be seen that the thicker is interlayer insulating film (SiO) IS1, the longer is MTTF. Presumably, this results from that the modulus of elasticity of interlayer insulating film IS1 is increased by increasing the thickness of interlayer insulating film IS1.

Based on the above-noted finding by the present inventors, it is possible to prevent electromigration by increasing the thickness of interlayer insulating film II5 in the structure in FIG. 26. The increased thickness of interlayer insulating film II5, however, increases the aspect ratio (depth/hole diameter) of via hole VH so that the step coverage in via hole VH of pad conductive layer PCL becomes worse. Accordingly, pad conductive layer PCL is disconnected or the resistance becomes high in via hole VH thereby reducing the reliability of the interconnection.

By contrast, in accordance with the present embodiment, insulating film SI3 of SiN is provided on diffusion preventing insulating film DP3 as shown in FIG. 16. Since the modulus of elasticity (Young's modulus) of SiN as insulating film SI3 is as high as 150 GPa or more and 250 GPa or less, it acts to suppress the volumetric expansion of copper interconnection layer CL3 when copper interconnection layer CL3 is heated. Therefore, the force of copper interconnection layer CL3 expanding is present in the interior of copper interconnection layer CL3 and compressive stress develops in the interior of copper interconnection layer CL3. When the internal stress of copper interconnection layer CL3 reaches the critical stress of the tension side, voids are likely to be formed due to electromigration in copper interconnection layer CL3. In the present embodiment, however, because of the compressive stress in the interior of copper interconnection layer CL3, the internal stress of copper interconnection layer CL3 hardly reaches the critical stress of the tension side. Thus, electromigration-induced voids can be prevented.

As described above, in the present embodiment, provision of insulating film SI3 on diffusion preventing insulating film DP3 can prevent electromigration in copper interconnection layer CL3, so that there is no need for increasing the thickness of interlayer insulating film II5. Accordingly, the aspect ratio of via hole VH can be reduced and therefore the disconnection or resistance increase of pad conductive layer PCL in via hole VH can be prevented, thereby enhancing the reliability of interconnection.

In addition, since pad conductive layer PCL is directly connected with copper interconnection layer CL3 in the present embodiment, there is no need for providing a plug conductive layer and the like between pad conductive layer PCL and copper interconnection layer CL3. Thus, there is no need for forming a plug conductive layer and the like, thereby simplifying the manufacturing processes and also simplifying the structure itself.

### Fourth Embodiment

In the third embodiment, the structure in which pad conductive layer PCL is in direct contact with the uppermost copper interconnection layer CL3 has been described. However, as long as pad conductive layer PCL is electrically connected with the uppermost copper interconnection layer CL3, it may be indirectly connected with the uppermost copper interconnection layer CL3 through a plug conductive layer. A structure in which pad conductive layer PCL is indirectly connected with the uppermost copper interconnection layer CL3 through a plug conductive layer will be described below as a fourth embodiment.

Referring to FIG. 28, the structure of the semiconductor device in the present embodiment differs from the structure in the third embodiment shown in FIG. 16 in that pad conductive layer PCL is indirectly connected with the uppermost copper interconnection layer CL3 through a plug conductive layer PLG.

In interlayer insulating film II5, insulating film SI3, and diffusion preventing insulating film DP3, via hole VH is formed which passes through these films II5, SI3 DP3 to reach copper interconnection layer CL3.

Plug conductive layer PLG is formed to fill in via hole VH. This plug conductive layer PLG is formed, for example, of tungsten (W). Pad conductive layer PCL is formed on interlayer insulating film II5 to electrically connect to the uppermost copper interconnection layer CL3 through plug conductive layer PLG.

Except for that described above, the structure of the present embodiment is almost the same with the structure of the third embodiment shown in FIG. 16. Therefore the same elements are denoted with the same reference characters and the description will not be repeated.

Now, a method of manufacturing the semiconductor device in accordance with the present embodiment will be described.

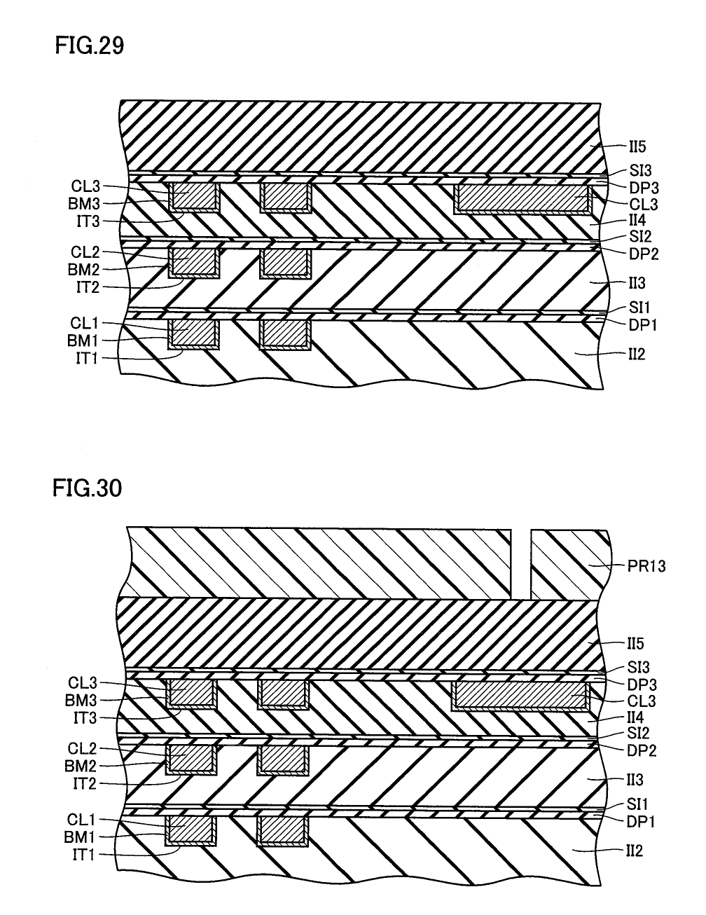

In the manufacturing method in accordance with the present embodiment, first, the steps in the third embodiment shown in FIG. 17-FIG. 19 are performed. Thereafter, referring to FIG. 29, interlayer insulating film II5 is formed, for example, at a thickness of 850 nm or less on insulating film SI3.

Referring to FIG. 30, a photoresist PR13 is applied on interlayer insulating film 115. Photoresist PR13 is patterned by the usual photolithography technique. Using the patterned resist pattern PRI3 as a mask, anisotropic etching is performed on interlayer insulating film II5, insulating film SI3, and diffusion preventing insulating film DP3. Thereafter, photoresist PR13 is removed, for example, by ashing.

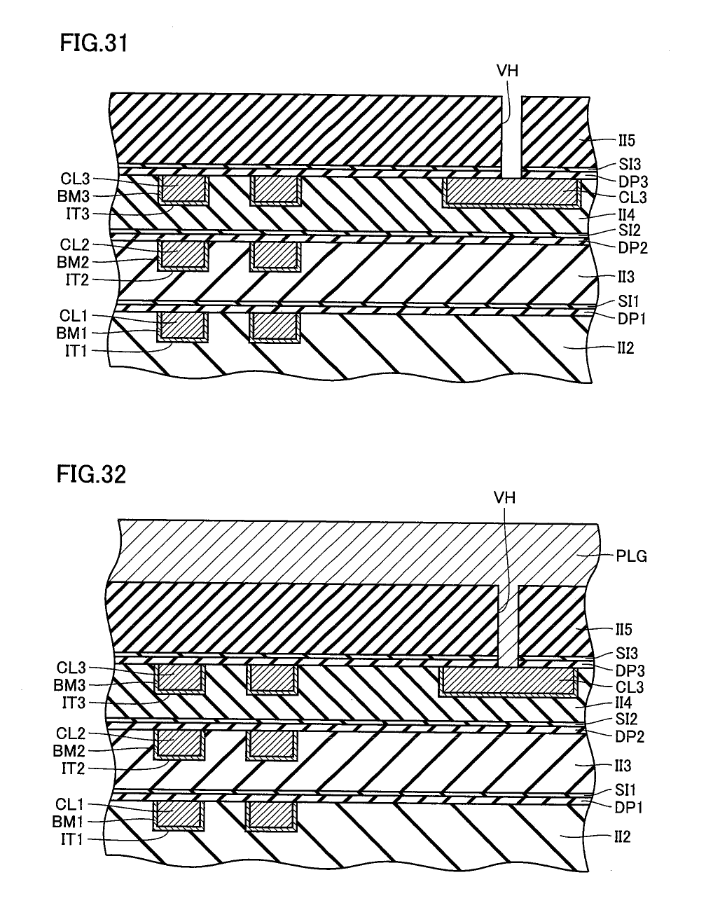

Referring to FIG. 31, through the aforementioned etching, via hole VH is formed which passes through interlayer insulating film II5, insulating film SI3, and diffusion preventing insulating film DP3 to reach copper interconnection layer CL3.

Referring to FIG. 32, conductive layer PLG, for example, of W is formed by sputtering to fill in via hole VH and cover interlayer insulating film II5. Conductive layer PLG is polished away by CMP.

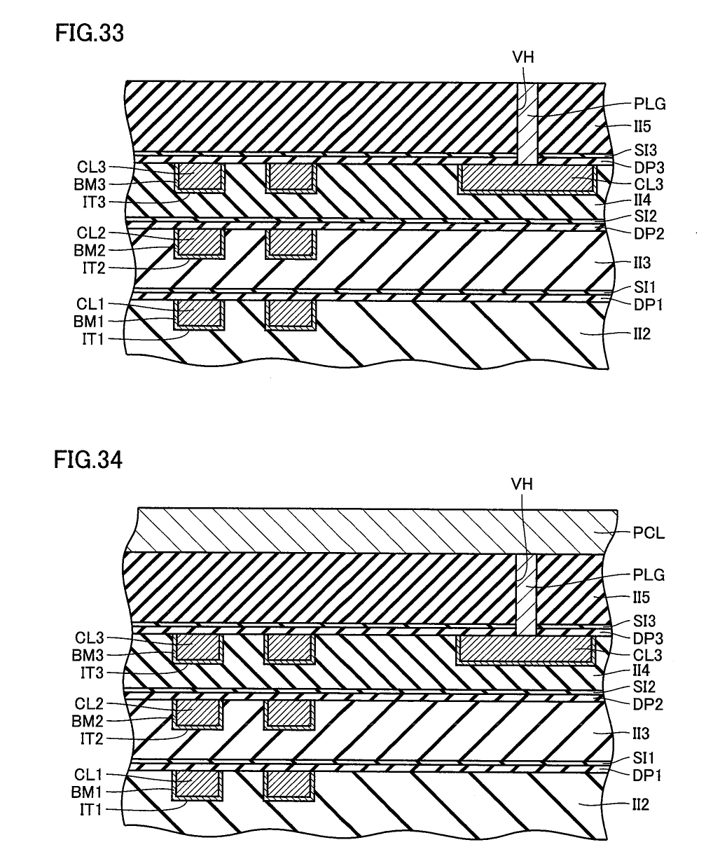

Referring to FIG. 33, through the aforementioned CMP, conductive layer PLG is polished away to such an extent that the surface of interlayer insulating film II5 is exposed. Accordingly, conductive layer PLG is left only in via hole VH, resulting in plug conductive layer PLG.

Referring to FIG. 34, conductive layer PCL, for example, of Al is formed by sputtering on interlayer insulating film II5 to be in contact with the upper surface of plug conductive layer PLG.

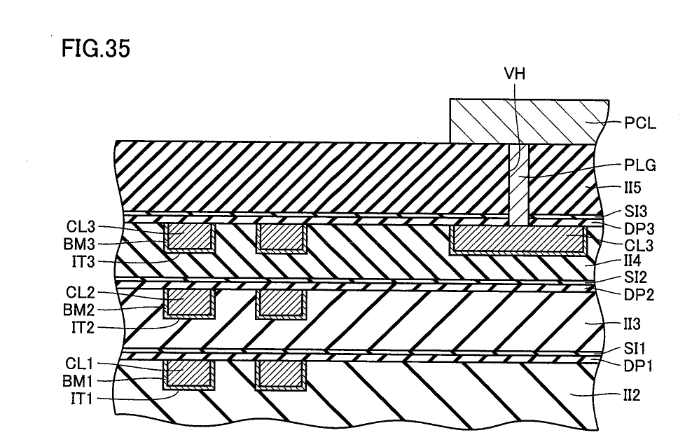

Referring to FIG. 35, conductive layer PCL is patterned by the usual photolithography and etching techniques. Thus, pad conductive layer PCL in contact with the upper surface of plug conductive layer PLG is formed from conductive layer PCL.

Thereafter, moisture protection film PV called passivation is formed, for example, by CVD to cover pad conductive layer PCL. This passivation film PV is patterned by the usual photolithography and etching techniques. Accordingly, opening PDO is formed in passivation film PV and the surface of the pad portion of pad conductive layer PCL is exposed from opening PDO, as shown in FIG. 28.

Through the above-noted steps, the semiconductor device in the present embodiment is manufactured.

Now, the operative effect of the present embodiment will be described in comparison with a comparative example.

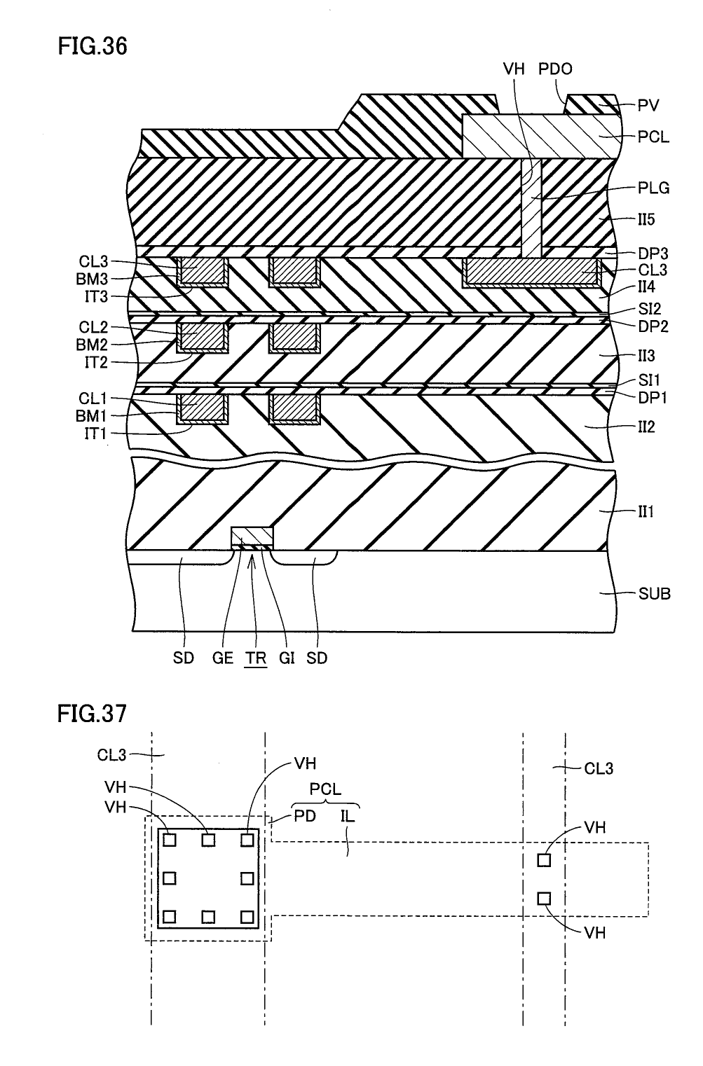

Referring to FIG. 36, the comparative example is structured by eliminating insulating film SI3 of SiN from the structure in the present embodiment shown in FIG. 28. Except for this, the structure of the comparative example shown in FIG. 36 is almost the same with the structure shown in FIG. 28. Therefore the same elements are denoted with the same reference characters and the description will not be repeated.

As described in the third embodiment, with the recent miniaturization and increased density of devices, it is likely that electromigration easily occurs in the uppermost copper interconnection layer CL3. In order to prevent the aforementioned electromigration, it is effective to increase the thickness of interlayer insulating film II5 on copper interconnection layer CL3. The increased thickness of interlayer insulating film II5, however, increases the aspect ratio (depth/hole diameter) of via hole VH. Thus, it is difficult to fill via hole VH with plug conductive layer PLG without a gap, and plug conductive layer PLG is disconnected or the resistance becomes higher, thereby deteriorating the reliability of interconnection.

By contrast, in accordance with the present embodiment, as shown in FIG. 28, insulating film SI3 of SiN is provided on diffusion preventing insulating film DP3. Therefore, similarly to the third embodiment, electromigration-induced voids in copper interconnection layer CL3 can be prevented. This eliminates the need for increasing the thickness of interlayer insulating film II5 so that the aspect ratio of via hole VH can be reduced. Accordingly, the disconnection or resistance increase of plug conductive layer PLG in via hole VH can be prevented, thereby enhancing the reliability of interconnection.

In addition, since plug conductive layer PLG is used in the present embodiment, the thickness of interlayer insulating film II5 can be increased as compared with the structure in the third embodiment shown in FIG. 16. Therefore, even if a Low-k material with a low mechanical strength is used for interlayer insulating films II2, II3 in FIG. 28, the mechanical strength can be secured by interlayer insulating film II5. Therefore, probing damages can be reduced when a probe is brought into contact with a pad at the time of measurement of electric characteristics using a prober, and the probing resistance can be improved.

It is noted that pad conductive layer PCL in the present embodiment may have a pad portion PD for wire bonding and an interconnection portion IL extending from pad portion PD, as shown in the plan view in FIG. 37. Interconnection portion IL is electrically connected with the underlying copper interconnection layer (the uppermost copper interconnection layer) CL3 through plug conductive layer PLG in via hole VH.

In this manner, pad conductive layer PCL has interconnection portion IL, so that the freedom of degree of circuit design can be improved.

In addition, since pad conductive layer PCL has interconnection portion IL, it can be electrically connected to the underlying copper interconnection layer (the uppermost copper interconnection layer) CL3 immediately below pad portion PD and also electrically connected to another copper interconnection layer CL3 immediately below interconnection portion IL. Accordingly, in operation, current flowing in pad conductive layer PCL can be fed separately to different copper interconnection layers CL3, so that the current density of the uppermost copper interconnection layer CL3 can be reduced.

Moreover, the hole diameter of via hole VH to be filled with plug conductive layer PLG can be made smaller than the hole diameter of via hole VH to directly connect pad conductive layer PCL with copper interconnection layer CL3 as shown in FIG. 16. Thus, it becomes possible to connect interconnection portion IL of pad conductive layer PCL to another copper interconnection layer CL3 through via hole VH.

In the foregoing third and fourth embodiments, interlayer insulating film II4 is formed, for example, of SiO and interlayer insulating films II2, II3 are formed, for example, of a Low-k material or SiO.

Furthermore, in the foregoing third and fourth embodiments, when the distance between insulating film SI3 and copper interconnection layer CL3 is increased, the stress effect of insulating film SI3 on copper interconnection layer CL3 is reduced. Therefore, the distance between insulating film SI3 and copper interconnection layer CL3 is preferably as close as possible, for example, preferably 30 nm or less.

Although MOS transistors have been described as devices formed on a semiconductor substrate in the foregoing first to fourth embodiments, any other device may be formed.

The present invention is advantageously applied in particular to a semiconductor device having an interconnection including copper and a method of manufacturing the same.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A semiconductor device comprising:
an interlayer insulating film;
an interconnection layer including copper formed in said interlayer insulating film;
a diffusion preventing insulating film made of at least one of silicon carbide and silicon carbide nitride formed to cover said interconnection layer including copper; and
an insulating film made of silicon nitride formed on said interconnection layer including copper with said diffusion preventing insulating film interposed.

2. The semiconductor device according to claim 1, wherein internal stress of said insulating film is less than or equal to −1 GPa.

3. The semiconductor device according to claim 1, further comprising:
an upper interlayer insulating film formed on said insulating film; and
an upper interconnection layer including copper formed in said upper interlayer insulating film.

4. The semiconductor device according to claim 1, further comprising:
an upper interlayer insulating film formed on said insulating film; and
a pad conductive layer formed on said upper interlayer insulating film to electrically connect to said interconnection layer through a via hole formed in said upper interlayer insulating film, said insulating film, and said diffusion preventing insulating film.

5. The semiconductor device according to claim 4, wherein said pad conductive layer includes a portion formed in said via hole.

6. The semiconductor device according to claim 4, further comprising a plug conductive layer filling in said via hole to electrically connect said interconnection layer and said pad conductive layer with each other.

7. The semiconductor device according to claim 4, wherein said pad conductive layer includes a pad portion and an interconnection portion extending from said pad portion.

8. A method of manufacturing a semiconductor device comprising the steps of:
forming an interlayer insulating film having a trench at a surface thereof;
forming an interconnection layer including copper in said trench of said interlayer insulating film;
forming a diffusion preventing insulating film made of at least one of silicon carbide and silicon carbide nitride to cover said interconnection layer including copper; and
forming an insulating film made of silicon nitride on said interconnection layer including copper with said diffusion preventing insulating film interposed.
